(19) United States
(12) Patent Application Publication
(10) Pub. No.: US 2025/0250674 A1
(43) Pub. Date: Aug. 7, 2025

(54) REVERSE RESISTIVITY IN TOPOLOGICAL SEMIMETAL GROWN BY ATOMIC LAYER DEPOSITION

(71) Applicant: AJOU UNIVERSITY INDUSTRY-ACADEMIC COOPERATION FOUNDATION, Suwon-si (KR)

(72) Inventors: Il Kwon OH, Gunpo-si (KR); Youngmin SONG, Suwon-si (KR)

(73) Assignee: AJOU UNIVERSITY INDUSTRY-ACADEMIC COOPERATION FOUNDATION, Suwon-si (KR)

(21) Appl. No.: 19/046,056

(22) Filed: Feb. 5, 2025

(30) Foreign Application Priority Data
Feb. 6, 2024 (KR) 10-2024-0018072
Jan. 20, 2025 (KR) 10-2025-0008172

(51) Int. Cl. C23C 16/455; C23C 16/08; C23C 16/56

(52) U.S. Cl. CPC C23C 16/45553; C23C 16/08; C23C 16/56

(57) ABSTRACT

The present invention relates to an ALD thin film with reverse resistivity, and a method for manufacturing the same, and more particularly, to a thin film with reverse resistivity obtained by depositing a specific precursor and a reactant using ALD, and a method for manufacturing the same.

### TECHNICAL FIELD

Generally, as the thickness of an ALD-deposited organic metal film decreases, the resistance increases, whereas the present invention relates to an ALD thin film with reverse resistivity, which has the opposite properties of a conventional ALD thin film, in which the resistance decreases as the thickness decreases, a manufacturing method for the same, and an interconnect using the same.

### BACKGROUND

As the line width decreases in the metal interconnect process during the back-end-off-line (BEOL) process, electrical resistance tends to increase due to surface and grain boundary scattering and so on.

As a next-generation interconnect metal, ruthenium (Ru) has advantages such as electromigration resistance and thermal stability compared to copper (Cu), and molybdenum (Mo) has advantages such as thermal stability and physical strength compared to copper (Cu), so they are being studied together with materials such as platinum (Pt) and cobalt (Co). However, their high resistivity (Cu: 1.7μΩ·cm, Mo: 26.4μΩ·cm, Ru: 7.6 μΩ·cm) and, in particular, the increase in resistance with decreasing thickness have limited their viability as a complete solution for next-generation interconnect processes.

Topological Weyl semimetals have been proposed as next-generation metal interconnect materials in very few recent studies. The surface of topological Weyl semimetals exhibits a disorder-tolerant conductive state, with electron transport primarily occurring through this surface. Due to these properties, it is reported to have a different tendency from existing metals, where the resistance decreases as the thickness decreases.

Materials such as NbAs and WTeₓ have been reported as topological Weyl semimetals with these properties. However, although there are reports on the possibility of reverse resistivity phenomenon through simulations such as first-principles calculations for NbAs, WTeₓ, etc., actual experimental research is extremely rare, and there are no experimental results via ALD. In the case of research through actual experiments, research is being conducted at the level of bulk thin films of 100 nm or more, not thin films, and in addition, WTeₓ et al. is reported to have resistivity levels of approximately 1000 μΩcm, which is a high resistivity level, and research on topological Weyl semimetals as a substitute for Cu is insufficient.

### SUMMARY

The present invention was completed by discovering an optimal topological Weyl semimetal having a reverse resistivity property when forming a thin film via ALD (atomic layer deposition). That is, the present invention aims to provide an ALD thin film with reverse resistivity suitable for application as a next-generation metal interconnect material and a manufacturing (forming) method for the same.

It is disclosed that the present invention was derived from the support of the following national research and development project.

### NATIONAL RESEARCH AND DEVELOPMENT PROJECT THAT SUPPORTED THIS INVENTION

[Assignment Base Year] 2024 [Assignment Unique Number] 2710005857 [Assignment Number] 00357895
[Name of the Ministry] Korea Ministry of Science and ICT [Assignment management (professional) organization name] National Research Foundation of Korea
[Research Project Name] Individual Basic Research (Korea Ministry of Science and ICT)
[Research Assignment Name] Study on Atomic-Level Ultrathin Films of Topological Semimetals with Reverse Resistivity
[Contribution rate] 9/10 [Name of Project Carrying Out Organization] Ajou University Industry-Academic Cooperation Foundation
[Research Period] 2024.04.01-2025.03.31

The ALD thin film with reverse resistivity of the present invention for solving the above-described problems includes a topological Weyl semimetal formed by ALD deposition and has a characteristic that the resistivity value decreases as the thickness decreases.

In a preferred embodiment of the present invention, the resistivity value of the ALD thin film with reverse resistivity may decrease by 10 μΩ·cm or more per 1 nm decrease in the thickness of the ALD thin film.

In a preferred embodiment of the present invention, the resistivity value may satisfy 570 μΩ·cm or less when the thickness is 10 nm or less.

In a preferred embodiment of the present invention, the topological Weyl semimetal may include a compound represented by Chemical Formula 1 or Chemical Formula 2 below:

MₓA_{y} [Chemical Formula 1]

where M is Ta (tantalum) or Nb (niobium), A is P (phosphorus) or As (arsenic), x and y mean a stoichiometric ratio, and x/y is 0.95 to 1.10,

M′ₓ(B₂)_{y} [Chemical Formula 2]

where M′ is W (tungsten) or Mo (molybdenum), B is Te (tellurium), x and y mean a stoichiometric ratio, and x/y is 0.95 to 1.10.

In a preferred embodiment of the present invention, the topological Weyl semimetal may be amorphous or nanocrystal-containing amorphous.

In a preferred embodiment of the present invention, the ALD thin film may not contain nanocrystals when it exceeds 5 nm.

In a preferred embodiment of the present invention, when the ALD thin film is less than or equal to 5 nm, the ALD thin film may include nanocrystals having an average particle diameter smaller than the thickness of the thin film and an average particle diameter of 2.2 nm or less.

According to another aspect, the present invention relates to a manufacturing method for an ALD thin film with reverse resistivity, the manufacturing method including: performing an ALD deposition process on a target substrate using a metal precursor and a reactant to form an ALD deposition layer containing a compound represented by Chemical Formula 1 or Chemical Formula 2 above, wherein the metal precursor includes a Ta (tantalum) precursor, a Nb (niobium) precursor, a W (tungsten) precursor, or a Mo (molybdenum) precursor.

In a preferred embodiment of the present invention, when the metal precursor is a Ta precursor or an Nb precursor, the reactant may include a phosphorus (P)-based compound or an arsenic (As)-based compound.

In a preferred embodiment of the present invention, when the metal precursor is a W precursor or a Mo precursor, the reactant may include a tellurium (Te)-based compound.

In a preferred embodiment of the present invention, the Ta precursor may include at least one selected from TaCl₅, TaF₅, TaI₅, TaBr₅, TaNp₃Cl₂, Ta(NEtMe)₅, Ta(NEt)(NEt₂)₃, Ta(NEt₂)₅, Ta(NMe₂)₅, Ta(OEt)₅, Ta(NtBu)(^{t}PrAMD)₂(NMe₂), Ta(NtBu)(NEt₂)₃, Ta(NtBu) (^{t}Bu₂pz)₃, and Ta(N^{t}Am)(NMe₂)₃.

In a preferred embodiment of the present invention, the Nb precursor may include at least one selected from NbCl₅, NbF₅, Nb(OEt)₅, Nb(NtBu)(NEt₂)₂(Cp), Nb(NtBu)(NEt₂)₃, and Nb(NtBu)(NEtMe)₃.

In a preferred embodiment of the present invention, the P-based compound may include at least one selected from PH₃, P(NMe₂)₃, ^{t}BuPH₂, P₂O₅, and PO(OMe)₃.

In a preferred embodiment of the present invention, the As-based compound may include at least one selected from As, AsH₃, As(NMe₂)₃, (Et₃Si)₃As, ^{t}BuAsH₂, and EtAsH₂.

In a preferred embodiment of the present invention, the W precursor may include at least one selected from WCl₅, WF₆, W(CO)₆, WH₂Cp₂, W₂(NMe₂)₆, W(NtBu)₂(NMe₂)₂, (C₆H₁₀)₃(CO)W, WH₂(ⁱPrCp)₂, and WO₂(^{t}BuAMD)₂.

In a preferred embodiment of the present invention, the Mo precursor may include at least one selected from MoCl₅, MoF₆, MoO₂Cl₂, Mo(CO)₆, Mo(NMe₂)₄, Mo(C₆H₅C₂H₅)₂(═Mo(EtBen)₂), Mo(MeCp)(CO)₂(NO), MoH₂(PrCp)₂, Mo(N^{t}Bu)₂(NEt₂)₂, Mo(N^{t}Bu)₂(NMe₂)₂, Mo(C₅H₁₁N)₂(C₅H₁₁NH)₂(═Mo(^{t}AmylN)₂(^{t}AmylNH)₂), Mo(^{t}BuN)₂(S^{t}Bu)₂, and MoCp(CO)₂(NO).

In a preferred embodiment of the present invention, the ALD deposition process may be performed by thermal atomic layer deposition (thermal ALD) or plasma enhanced atomic layer deposition (PE-ALD) process.

In a preferred embodiment of the present invention, the ALD deposition process may perform, once or repeatedly more than once, a cycle, the cycle including: step 1 of forming a metal deposition layer on a target substrate by supplying a vaporized metal precursor into a reaction chamber via a carrier gas; step 2 of purging the inside of the chamber with a purge gas; step 3 of supplying a reactant into the chamber to form a deposition layer containing a compound represented by Chemical Formula 1 or Chemical Formula 2 above formed by reacting the metal deposition layer with the reactant; step 4 of purging the inside of the chamber with a purge gas after performing step 3; step 5 of treating the inside of the chamber with H₂ after performing step 4; and step 6 of purging the inside of the chamber with a purge gas after performing step 5.

In a preferred embodiment of the present invention, the temperature of the target substrate in step 1 may be 100 to 500° C., and the process temperature in steps 1 to 3 may be 100 to 500° C.

In a preferred embodiment of the present invention, the H₂ treatment may be performed by H₂ gas treatment, H₂ plasma treatment, or H₂ radical treatment.

In a preferred embodiment of the present invention, in the manufacturing (formation) method for an ALD thin film with reverse resistivity of the present invention, after completing the ALD deposition process, an oxidation barrier film may be further formed on the surface protruding outward from the ALD deposition layer, followed by an annealing process.

In a preferred embodiment of the present invention, the oxidation barrier film may be a silicon nitride (SiNₓ) ALD deposition layer with a thickness of 1 to 10 nm.

In a preferred embodiment of the present invention, the annealing may be performed at 300 to 850° C. in a vacuum atmosphere or an inert gas.

According to yet another aspect, the present invention provides an interconnect using the previously described ALD thin film with reverse resistivity.

The ALD thin film with reverse resistivity of the present invention can provide a new next-generation metal interconnect material because it has a feature of decreasing electrical resistance as the thickness is reduced, that is, a reverse resistivity phenomenon through Weyl fermions. In addition, the PVD (physical vapor deposition) and CVD (chemical vapor deposition) thin films using existing topological Weyl semimetals had the problem of having to be performed under harsh conditions of high temperature of about 800° C. and low pressure of 10-6 torr, but the ALD thin film of the present invention can be deposited under relatively lower temperature and higher pressure conditions and can provide an ALD thin film with reverse resistivity in which the oxidation problem of the deposited thin film is alleviated via oxidation barrier film deposition in the same chamber. In particular, ALD is a process that exhibits excellent conformality, unlike PVD and CVD, and has the distinct advantage of being able to deposit thin films conformally even on complex three-dimensional structures. These characteristics are key factors in solving the problem of forming thin films in complex structures that were difficult to implement in conventional PVD and CVD processes due to conformality issues in addition to process temperature and pressure.

### BRIEF DESCRIPTION OF THE DRAWINGS

FIG. 1 is a schematic diagram of equipment used to manufacture a topological Weyl semimetal thin film using plasma ALD of the present invention.

FIG. 2 is a process schematic diagram for one cycle of a topological Weyl semimetal thin film formation process conducted in Example 1.

FIG. 3 shows a result of measuring ALD growth characteristics of a TaP thin film conducted in Experimental Example 1.

FIG. 4 shows XPS measurement results according to a target substrate and deposition temperature of the TaP thin film conducted in Experimental Example 1.

FIG. 5 shows a result of evaluating resistivity characteristics of a target substrate and a TaP ALD thin film manufactured at a deposition temperature of 250° C. conducted in Experimental Example 2.

FIG. 6 shows a result of evaluating resistivity characteristics of a target substrate and a TaP ALD thin film manufactured at a deposition temperature of 170° C. conducted in Experimental Example 2.

FIG. 7 shows XRD analysis measurement results according to thickness and annealing conditions of a TaP ALD thin film conducted in Experimental Example 3.

### DETAILED DESCRIPTION OF THE EMBODIMENTS

In the present invention, the term “thin film” means a deposition layer and/or a film formed via ALD.

In the present invention, the expression “reverse resistivity” means a characteristic in which the resistivity value decreases as the thickness of the thin film decreases.

Hereinafter, a method of manufacturing an ALD thin film with reverse resistivity of the present invention will be described in more detail.

The ALD thin film with reverse resistivity of the present invention can be manufactured by performing an atomic layer deposition (ALD) process, preferably a plasma enhanced atomic layer deposition (PE-ALD) process.

In the ALD thin film with reverse resistivity of the present invention, an ALD deposition layer including a compound represented by Chemical Formula 1 or Chemical Formula 2 is formed by performing an ALD deposition process with a metal precursor and a reactant on a target substrate.

MₓA_{y} [Chemical Formula 1]

In Chemical Formula 1, M is Ta (tantalum) or Nb (niobium), A is P (phosphorus) or As (arsenic), x and y mean a stoichiometric ratio, x/y is 0.95 to 1.10, preferably x/y is 0.97 to 1.06, and more preferably x/y is 0.98 to 1.02.

M′ₓ(B₂)_{y} [Chemical Formula 2]

In Chemical Formula 2, M′ is W (tungsten) or Mo (molybdenum), B is Te (tellurium), x and y mean a stoichiometric ratio, x/y is 0.95 to 1.10, preferably x/y is 0.97 to 1.06, and more preferably x/y is 0.98 to 1.02.

The metal precursor includes a Ta (tantalum) precursor, a Nb (niobium) precursor, a W (tungsten) precursor, or a Mo (molybdenum) precursor.

The reactant varies depending on the type of metal precursor, and for a preferred embodiment, when the metal precursor is a Ta precursor or an Nb precursor, the reactant may include a phosphorus (P)-based compound or an arsenic (As)-based compound.

The Ta precursor may include at least one selected from TaCl₅, TaF₅, TaI₅, TaBr₅, Ta(NEtMe)₅, Ta(NEt)(NEt₂)₃, Ta(NEt₂)₅, Ta(NMe₂)₅, Ta(OEt)₅, TaNp₃Cl₂, Ta(N^{t}Bu)(^{t}PrAMD)₂(NMe₂), Ta(N^{t}Bu)(NEt₂)₃, Ta(N^{t}Bu) (^{t}Bu₂pz)₃, and Ta(N^{t}Am) (NMe₂)₃, preferably, may include at least one selected from Ta(NMe₂)₅, Ta(NEt₂)₅, Ta(N^{t}Bu)(NEt₂)₃, and Ta(N^{t}Am)(NMe₂)₃, and more preferably, may include at least one selected from Ta(NMe₂)₅, Ta(NEt₂)₅, and Ta(N^{t}Bu)(NEt₂)₃.

And, the Nb precursor may include at least one selected from NbCl₅, NbF₅, Nb(OEt)₅, Nb(N^{t}Bu)(NEt₂)₂(Cp), Nb(N^{t}Bu)(NEt₂)₃, and Nb(N^{t}Bu)(NEtMe)₃, preferably, may include at least one selected from Nb(N^{t}Bu)(NEt₂)₃, Nb(N^{t}Bu)(NEtMe)₃, and NbCl₅, and more preferably, may include at least one selected from Nb(N^{t}Bu)(NEt₂)₃, and Nb(N^{t}Bu)(NEtMe)₃.

In addition, among the reactants, the P-based compound may include at least one selected from PH₃, P(NMe₂)₃, ^{t}BuPH₂, P₂O₅, and PO(OMe)₃, preferably, may include at least one selected from PH₃, ^{t}BuPH₂, and P(NMe₂)₃, and more preferably, may include at least one selected from PH₃ and ^{t}BuPH₂.

In addition, among the reactants, the As-based compound may include at least one selected from As, AsH₃, As(NMe₂)₃, (Et₃Si)₃As, ^{t}BuAsH₂, and EtAsH₂, preferably, may include at least one selected from AsH₃, ^{t}BuAsH₂, and As, and more preferably, may include at least one selected from AsH₃ and ^{t}BuAsH₂.

In addition, when the metal precursor is a W precursor or a Mo precursor, the reactant may include a tellurium (Te)-based compound.

The W precursor may include at least one selected from WCl₅, WF₆, W(CO)₆, WH₂Cp₂, W₂(NMe₂)₆, W(N^{t}Bu)₂(NMe₂)₂, (C₆H₁₀)₃(CO)W, WH₂(ⁱPrCp)₂, and WO₂(^{t}BuAMD)₂, preferably, may include at least one selected from W(N^{t}Bu)₂(NMe₂)₂, W₂(NMe₂)₆, and WCl₅, more preferably, may include at least one selected from, and yet more preferably, may include at least one selected from W(N^{t}Bu)₂(NMe₂)₂, and W₂(NMe₂)₆.

And, the Mo precursor may include at least one selected from MoCl₅, MoF₆, MoO₂Cl₂, Mo(CO)₆, Mo(NMe₂)₄, Mo(C₆H₅C₂H₅)₂(═Mo(EtBen)₂), Mo(MeCp)(CO)₂(NO), MoH₂(ⁱPrCp)₂, Mo(N^{t}Bu)₂(NEt₂)₂, Mo(N^{t}Bu)₂(NMe₂)₂, Mo(C₅H₁₁N)₂(C₅H₁₁NH)₂(═Mo(^{t}AmylN)₂(^{t}AmylNH)₂), Mo(^{t}BuN)₂(S^{t}Bu)₂, and MoCp(CO)₂(NO), preferably, may include at least one selected from Mo(N^{t}Bu)₂(NEt₂)₂, Mo(NMe₂)₄, and Mo(EtBen)₂, and more preferably, may include at least one selected from Mo(N^{t}Bu)₂(NEt₂)₂ and Mo(NMe₂)₄.

And, the Te-base compound, which is a reactant, may include at least one selected from Te, Te(SiEt₃)₂, Et₂Te, MeAyTe, Te(SiMe₃)₂, Te(OEt)₄, Te(GeMe₃)₂, and Me₈Si₄Te₂, more preferably, may include at least one selected from Te(SiMe₃)₂, Et₂Te, and Te, and yet more preferably, may include at least one selected from Te(SiMe₃)₂ and Et₂Te.

The process of forming a thin film by performing a thermal atomic layer deposition (Thermal ALD) or plasma enhanced atomic layer deposition (PE-ALD) process using the above-described precursors and reactants will be described in more detail as follows.

The cycle including step 1 of forming a metal deposition layer on a target substrate by supplying a vaporized metal precursor into a reaction chamber via a carrier gas; step 2 of purging the inside of the chamber with a purge gas; step 3 of supplying a reactant into the chamber to form a deposition layer including a compound represented by Chemical Formula 1 or Chemical Formula 2 above formed by reacting the metal deposition layer with the reactant; step 4 of purging the inside of the chamber with a purge gas after performing step 3; step 5 of treating the inside of the chamber with H₂ after performing step 4; and step 6 of purging the inside of the chamber with a purge gas after performing step 5 may be performed once or repeatedly more than once.

The chamber in which the above steps 1 to 6 are performed can use ALD equipment with a 6-inch showerhead type chamber, which is an example and is not limited thereto.

Next, the target substrate of step 1 may use a silicon (Si) substrate, a silica (SiO₂) substrate, a platinum (Pt) substrate, a germanium (Ge) substrate, or a gallium nitride (GaN) substrate, and it preferably may use a silicon substrate but is not limited thereto.

The target substrate temperature in step 1 may be 100 to 500° C., preferably 150 to 400° C., more preferably 160 to 200° C., and in this case, if the target substrate temperature is less than 100° C., there may be a problem that the reactivity and surface saturation of the precursor may be insufficient, resulting in lower growth rate and lower film conformality, and impurities in the thin film may increase due to the precursor not being completely decomposed. In addition, if the target substrate temperature exceeds 500° C., the precursor may be thermally decomposed in the gas phase, losing the conformal growth characteristics of ALD, and forming a non-conformal film similar to CVD, and the quality of the thin film may deteriorate due to an increase in residual by-products due to high temperature.

In addition, the carrier gas in step 1 may include at least one selected from argon (Ar), nitrogen (N₂), helium (He), and hydrogen (H₂), and preferably argon may be used.

The metal precursor injection conditions for forming the metal deposition layer in Step 1 are appropriately performed when the distance between the substrate and the showerhead is in the range of 25 to 35 mm, preferably 28 to 32 mm, and when performing atomic layer deposition by injecting a metal precursor, it is desirable to set the precursor exposure time to the fastest time for the growth per cycle (GPC) to become constant while proceeding with the precursor exposure to ensure a self-limiting reaction due to surface saturation. If the precursor exposure time is shorter than the fastest time for GPC to become constant, it is highly likely that the precursor reaction on the surface is incomplete, and thus uniformity of deposition thickness is degraded, and self-limiting characteristics of ALD reaction are not ensured. On the other hand, if the precursor exposure time exceeds the fastest time for GPC to become constant, an undesired reaction may occur due to excessive adsorption of the precursor on the surface or may affect the composition and structure of the deposition layer, thereby reducing process reproducibility. Therefore, the precursor exposure time should be optimized according to the characteristics of each precursor and the process conditions, and it is important to secure the uniformity and reproducibility of the ALD process by setting it based on the time at which GPC becomes constant.

As a preferable example, when the substrate temperature is 160 to 200° C., it is appropriate to inject the metal precursor so that the appropriate GPC is 0.7 to 1.25, more preferably GPC is 0.8 to 1.20, and the precursor exposure time is in the range of 3 to 5 seconds.

Next, the purging in step 2 is a process of removing a non-deposited metal precursor in a chamber, and nitrogen (N₂), argon (Ar), and neon (Ne) may be used as the purge gas, preferably argon may be used. As a preferred example, purging may be performed by injecting and discharging 400 to 600 sccm of argon for 15 to 90 seconds. If purging is insufficient for less than 15 seconds in the ALD process, precursor residues or reaction by-products may not be completely removed, which may cause problems such as growth non-uniformity of thin films, particle generation by spontaneous chemical reactions, and increased chemical contamination. This leads to a deterioration in the chemical composition and electrical properties of the thin film, a decrease in selective reactivity and reaction efficiency, and a decrease in the filling ability within the three-dimensional structure, which in turn adversely affects process reproducibility and reliability. Therefore, sufficient purging is essential to ensure thin film quality and maintain the precision and uniformity of the ALD process.

Next, the reactants in step 3 are supplied into the chamber via a carrier gas, and in this case, the carrier gas may include at least one selected from argon (Ar), nitrogen (N₂), helium (He), and hydrogen (H₂), and helium may be preferably used. The conditions for thermal atomic layer deposition and plasma atomic layer deposition for forming a metal deposition layer through reactant injection in step 3 are appropriately performed when the distance between the substrate and the showerhead is in the range of 25 to 35 mm, preferably 28 to 32 mm, and when performing atomic layer deposition by injecting reactants, the reactant exposure time is preferably set to the fastest time for GPC (Growth Per Cycle) to become constant while proceeding with reactant exposure to ensure a self-limiting reaction due to surface saturation. If the reactant exposure time is shorter than the fastest time for GPC to become constant, surface saturation may not occur, resulting in non-uniformity in thin film growth and a decrease in GPC, which may deteriorate process reproducibility. Conversely, if the reactant exposure time exceeds the fastest time for GPC to become constant, it not only results in unnecessary reactant waste and increased process time, but also may cause excessive reactant to accumulate reactant molecular residues on the thin film surface, potentially causing contamination or particle formation. Therefore, optimizing the reactant exposure time to match the fastest time for GPC to become constant is key to ensuring both process efficiency and thin film quality.

As a preferable example, when the deposition temperature is 160 to 200° C., it is appropriate to inject the metal precursor so that the appropriate GPC is 0.7 to 1.25, more preferably GPC is 0.8 to 1.20, and the precursor exposure time is in the range of 3 to 5 seconds.

When performing atomic layer deposition in step 3 by plasma atomic layer deposition, it may be performed under the following conditions. For plasma frequency, a very high frequency (VHF) plasma frequency of 50 Hz or higher is used, rather than the commonly used 13.56 MHz, to minimize thin film damage. If using a plasma frequency of 13.56 MHz, which is used in a general plasma atomic layer deposition process, there is a problem that the sample surface may be damaged due to the high ion energy, but if a VHF (Very High Frequency) plasma frequency of 50 Hz or higher is used, the ion energy may be lowered while the ion density may be increased, thereby minimizing damage to the thin film. Therefore, the plasma frequency is set to 50 to 70 MHz and the plasma power to 70 to 90 W, preferably the plasma frequency is set to 55 to 70 MHz and the plasma power to 75 to 90 W, and more preferably the plasma frequency is set to 58 to 65 MHz and the plasma power to 78 to 85 W, so that the thin film damage caused by the plasma may be minimized. The amount of reactant input is controlled according to the amount of metal precursor input in step 1, and specifically, may be input by controlling it to satisfy the x/y values of Chemical Formula 1 and/or Chemical Formula 2.

And, the process temperature of each of steps 1 to 3 may be 100 to 500° C., preferably 150 to 450° C., and more preferably 160 to 200° C.

Next, the purging in step 4 is a process for removing over-deposited reactant components, etc., and purging may be performed using the same method and conditions as step 2.

And, H₂ treatment in step 5 is a process to remove reactants such as P, As, or Te that remain after purging. In particular, reactants are easily decomposed in high temperature and plasma environments, and are over-deposited on the sample surface, inhibiting uniform atomic layer deposition. Therefore, removal of the over-deposited residual reactants is necessary. To remove the remaining over-deposited reactants, H₂ gas treatment, H₂ plasma treatment, or H₂ radical treatment may be performed.

For H₂ plasma treatment, it may be performed under the same conditions as the plasma atomic layer deposition conditions (frequency, power, time) in step 3, thereby minimizing thin film damage. For example, in a preferred embodiment, the plasma frequency is set to 50 to 70 MHz, the plasma power is set to 70 to 90 W, preferably the plasma frequency is set to 55 to 70 MHz, the plasma power is set to 75 to 90 W, more preferably the plasma frequency is set to 58 to 65 MHz, the plasma power is set to 78 to 85 W, and a gas containing 90 to 97 volume % of Ar and 3 to 10 volume % of H₂ is injected to perform plasma treatment for 15 to 40 seconds. If the gas injection time is less than 15 seconds, there is a problem that the remaining reactants are not removed sufficiently due to insufficient H₂ plasma treatment, and thus ALD deposition of self-limiting reaction through surface saturation does not occur. If the gas injection time exceeds 40 seconds, there may be a problem in that the etching phenomenon may occur in which the thin film formed due to excessive H₂ plasma treatment is removed. In addition, step 6 is a purging process to remove foreign substances (residual gas, by-products) remaining in the chamber where step 5 was performed, and may be performed using the same method and conditions as step 2 and/or step 4.

For the thin film formed by performing steps 1 to 6 described above, after completing the ALD deposition process, an oxidation barrier film may be further formed on the surface protruding outward from the ALD deposition layer, followed by an annealing process.

A preferred embodiment of the above-mentioned oxidation barrier film may be a silicon nitride (SiNx) ALD deposition layer with a thickness of 1 to 10 nm, and preferably a SiNx ALD deposition layer with a thickness of 1 to 5 nm.

And, the annealing is performed to obtain lower resistivity and may be performed at 300 to 850° C. under a vacuum atmosphere or an inert gas (He, N₂ or Ar), preferably at 380 to 650° C., and more preferably at 380 to 520° C.

The ALD thin film with reverse resistivity of the present invention fabricated by the method described above includes a topological Weyl semimetal formed by ALD deposition and has a characteristic that the resistivity value decreases as the thickness decreases, and preferably, the resistivity value may decrease by 10 μΩ·cm or more when the thickness decreases by 1 nm.

As a specific example, the ALD thin film with reverse resistivity may satisfy a resistivity value of 570 μΩ·cm or less when the thickness is 10 nm or less, preferably, the resistivity value may satisfy a resistivity value of 500 μΩ·cm or less when the thickness is 5 nm or less, and more preferably, the resistivity value may satisfy a resistivity value of 440 μΩ·cm when the thickness is 1 to 4 nm.

In this case, the resistivity value is measured based on a non-contact sheet resistance measurement method, which is a method of measuring surface resistance without contacting the surface of a sample using an eddy current sensor. This method is an efficient resistance measurement method that can accurately evaluate the conductivity of a sample without direct contact with the sample, thereby minimizing damage to the sample. The final resistivity of the sample can be obtained by multiplying the non-contact sheet resistance measurement value of the sample by the thickness of the sample (see Equation 1).

$$Sample resistivity ( Ωcm ) = Sample sheet resistance ( Ω / □ ) \times Sample thickness ( cm ) \qquad [ Equation 1 ]$$

The topological Weyl semimetal constituting the ALD thin film with reverse resistivity of the present invention may be amorphous and may further locally include in part nanocrystals.

For example, when the ALD thin film exceeds 5 nm, it may not contain nanocrystals, and when the ALD thin film is 5 nm or less, it may contain nanocrystals having an average particle diameter smaller than the thin film thickness and an average particle diameter of 2.2 nm or less, preferably nanocrystals having an average particle diameter of 1.2 nm or less.

The ALD thin film of the present invention, which is manufactured by the method described above and is composed of a topological Weyl semimetal having a reverse resistivity property, may be applied as a next-generation interconnect material.

Hereinafter, the present invention will be described in more detail through the following examples, but the following examples are not intended to limit the scope of the present invention, which should be construed to aid understanding of the present invention.

### EXAMPLES

### Example 1: Fabrication of Topological Weyl Semimetal Thin Films Via Plasma ALD

### (1) Fabrication of Topological Weyl Semimetal Thin Films According to Temperature

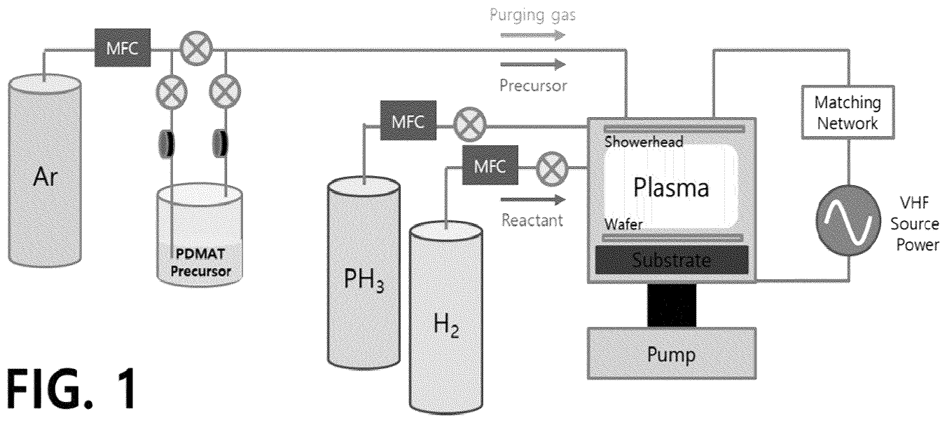

A topological Weyl semimetal thin film was fabricated via plasma ALD using ALD equipment with a 6-inch showerhead-type chamber, as described below. A schematic diagram of the equipment is shown in FIG. 1. In this case, the distance between the target substrate (Si substrate) and the showerhead in the chamber was fixed at 30 mm.

Ta(NMe₂)₅ (=PDMAT) was used as a metal precursor, and it was stored and used in a stainless steel canister. The metal precursor delivery line was heated to 80° C. to prevent condensation of the metal precursor. The metal precursor was vaporized at 70° C. and 20 sccm of Ar carrier gas was injected (vapor pressure 30 mtorr or less).

Via the plasma ADL deposition process, the vaporized metal precursor was supplied into the reaction chamber via a carrier gas, and the metal precursor was deposited on the target substrate for 3 seconds.

Next, 500 sccm of Ar gas was injected into the chamber to perform purging for 60 seconds.

Subsequently, a mixed gas (He 95 volume %) of PH₃ and He, the reactants, was deposited on the target substrate, where the metal precursor had been deposited, at a flow rate of 100 sccm via plasma ALD. At this time, the plasma frequency was set to 60 MHz and the plasma power was set to 80 W, and deposition was performed for 5 seconds.

Next, 500 sccm of Ar gas was injected into the chamber to perform purging for 60 seconds. Subsequently, 100 sccm of mixed gas (Ar 96 volume %) mixed with H₂ and Ar was injected onto the top where the reactants were deposited, and H₂ plasma treatment was performed to remove over-deposited P. In this case, the plasma frequency was set to 60 MHz and the plasma power was set to 80 W, and plasma treatment was performed for 30 seconds.

Next, re-purging was performed for 60 seconds by injecting 500 sccm of Ar gas into the chamber. 46 cycles were performed when, based on the 10 nm thickness target, target substrate and deposition temperature conditions were 300° C., 90 cycles at 250° C., 100 cycles at 200° C., and 104 cycles at 170° C.

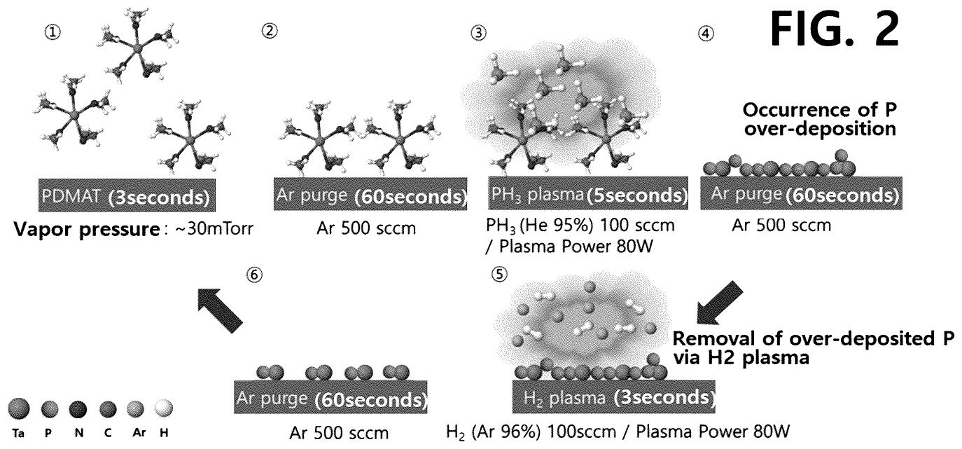

When performing the plasma ALD process, the temperature of the target substrate on which the metal precursor is deposited and the temperature conditions within the chamber when performing deposition of the metal precursor and reactant were changed to 300° C., 250° C., 200° C., and 170° C., respectively, thereby fabricating an ALD thin film containing a topological Weyl semimetal represented by the Chemical Formula 1-1 below. To aid understanding, a process schematic diagram for one cycle is shown in FIG. 2 as a specific example.

MₓA_{y} [Chemical Formula 1-1]

In Chemical Formula 1-1, M is Ta (tantalum) and A is p (phosphorus).

### Experimental Example 1: Analysis of ALD Growth Characteristics of Thin Films

### (1) Characterization of ALD Growth Characteristics of ALD Thin Films

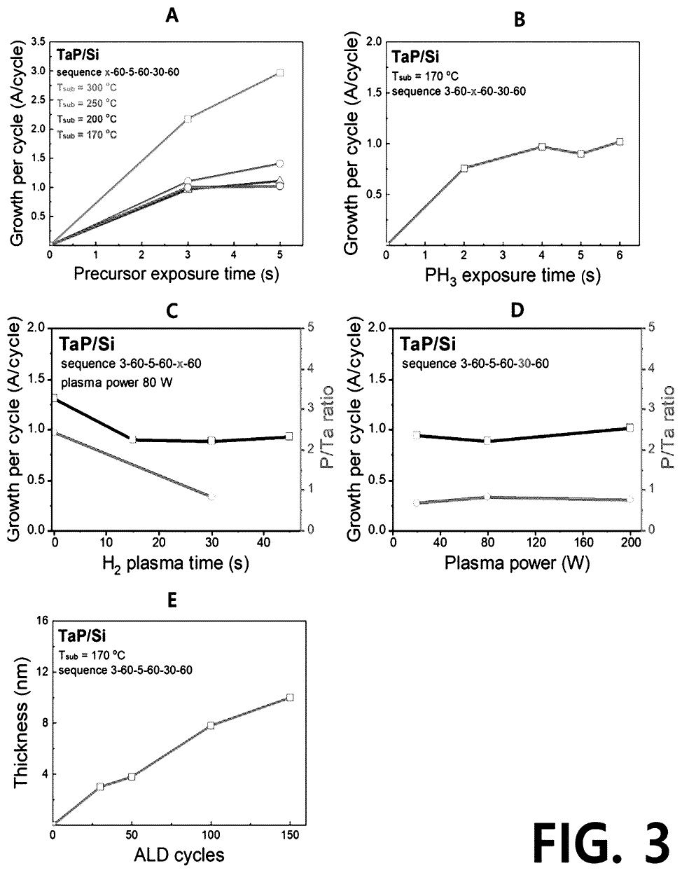

To characterize the ALD growth characteristics for each thin film of Example 1 fabricated by performing the target substrate and deposition temperature conditions of 300° C., 250° C., 200° C., and 170° C., the growth characteristics according to precursor exposure time and the metal precursor thermal decomposition characteristics according to temperature (A), the growth characteristics according to reactant exposure time (B), the growth characteristics according to H₂ plasma exposure time (C), the growth characteristics according to plasma power (D), and the growth characteristics according to the number of ALD cycles (E) are shown in FIG. 3, respectively.

Referring to A of FIG. 3, in the case of 300° C. and 250° C., the GPC (growth per cycle), which indicates the growth rate per cycle according to the precursor injection time, shows a tendency to continuously increase without saturation, and through this, it was confirmed that the metal precursor undergoes thermal decomposition in a high-temperature environment.

In addition, as the process temperature was lowered from 300° C. to 200 to 170° C., the increase in GPC (growth per cycle) according to the precursor injection time tended to be less prominent, and it was confirmed that when the precursor was injected for 3 seconds or more, the GPC no longer increased regardless of the precursor injection time and became saturated. Through this, it was confirmed that the self-limiting ALD reaction due to surface saturation of the precursor proceeded in the range of 170 to 200° C., and it was confirmed that the optimal temperature for TaP ALD is 200° C. or less, preferably 170° C. In addition, it was confirmed that the TaP ALD optimized precursor injection time was 5 seconds or less, preferably 3 seconds.

Referring to B of FIG. 3, GPC according to the reactant injection time can be confirmed at a temperature of 170° C. When reactants were injected for 5 seconds or more, it was confirmed that the GPC no longer increased regardless of the injection time and became saturated. This confirms that a self-limiting ALD reaction proceeds due to surface saturation of the reactant at 170° C., and through this, it can be confirmed that the optimal reactant injection time for TaP ALD is 6 seconds or less, preferably 5 seconds.

Referring to C of FIG. 3, the ratio of Ta to P and GPC according to the H₂ plasma injection time can be confirmed. If H₂ plasma treatment is not performed, a high GPC and a high P/Ta ratio can be confirmed, and through this, it can be confirmed that over-deposition of the reactants occurs. If H₂ plasma treatment is performed for 30 seconds or more, it can be confirmed that low GPC and stoichiometric P/Ta tend to be maintained regardless of injection time, and through this, it can be confirmed that over-deposited reactants are removed. Through this, it was confirmed that the TaP ALD optimized H₂ plasma injection time is 40 seconds or less, preferably 25 to 35 seconds.

Referring to D of FIG. 3, the ratio of Ta to P and GPC according to the H₂ plasma power can be confirmed. When H₂ plasma power of 80 W or more is used, it was possible to confirm the tendency to maintain constant GPC and stoichiometric P/Ta regardless of power, and through this, it was confirmed that TaP ALD optimized H₂ plasma power was 200 W or less, preferably 70 to 90 W.

In addition, referring to E of FIG. 3, the thickness of the thin film according to the number of ALD cycles at a temperature of 170° C. can be confirmed. Linear growth can be observed with the number of cycles, and this confirms that the atomic-scale thickness can be precisely controlled and deposited via the optimized TaP ALD.

### (2) Topological Weyl Semimetal Composition Properties of ALD Thin Films

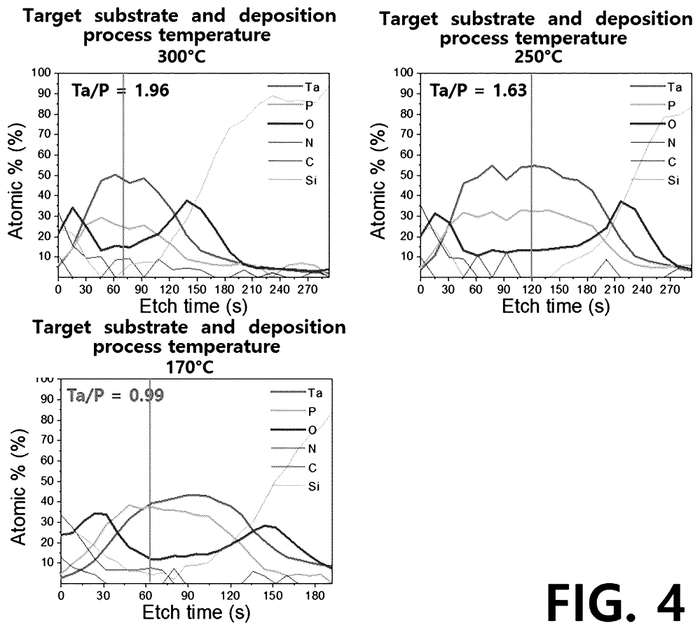

X-ray photoelectron spectroscopy (XPS) was performed on the ALD thin films formed by performing 46 cycles when, based on the 10 nm thickness target, target substrate and deposition temperature conditions were 300° C., 90 cycles at 250° C., 100 cycles at 200° C., and 104 cycles at 170° C., and the XPS measurement results of each thin film fabricated by performing at 300° C., 250° C., and 170° C. are shown in Table 1 and FIG. 4 below.

TABLE 1

| Target substrate | | x/y value |
|---|---|---|
| temperature and | | of Chemical |
| deposition temperature | Thin film thickness | Formula 1-1 |
| 300° C. | 10 nm | 1.96 |
| 250° C. | 10 nm | 1.63 |
| 170° C. | 10 nm | 0.99 |

Referring to A of FIG. 3 and FIG. 4, GPC saturation was suppressed due to the thermal decomposition of Ta precursors at temperatures of 300° C. and 250° C., and TaP, which is rich in Ta, was deposited. On the other hand, GPC saturation was observed at 170° C., and TaP with a stoichiometric ratio of Ta and P close to 1:1 was deposited.

Through this, it was confirmed that the self-limiting ALD reaction due to surface saturation proceeded in the range of 170 to 200° C., and the optimal temperature for TaP ALD is 200° C. or less, preferably 170° C.

### Example 2

Plasma ALD was performed on a Si substrate in the same manner as in Example 1 to fabricate an ALD thin film (TaP) represented by Chemical Formula 1-1, and it was performed under the target substrate and deposition temperature of 250° C. and 170° C., and the cycle was repeatedly performed to fabricate a thin film having various thicknesses as shown in Table 2.

Next, a 3 nm thick SiNₓ ALD deposition layer (oxidation barrier layer) was formed on the ALD thin film, and then annealing was performed at 400° C., 500° C., or 600° C. for 10 minutes under an N₂ atmosphere or a vacuum atmosphere.

### Experimental Example 2: Evaluation of Resistivity Characteristics of ALD Thin Films

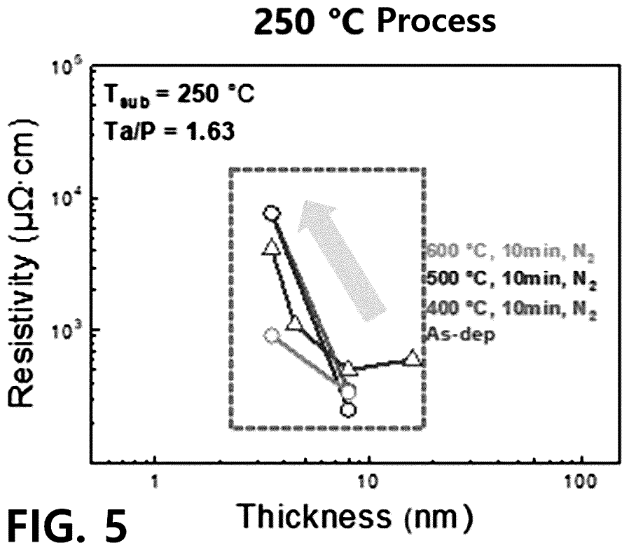

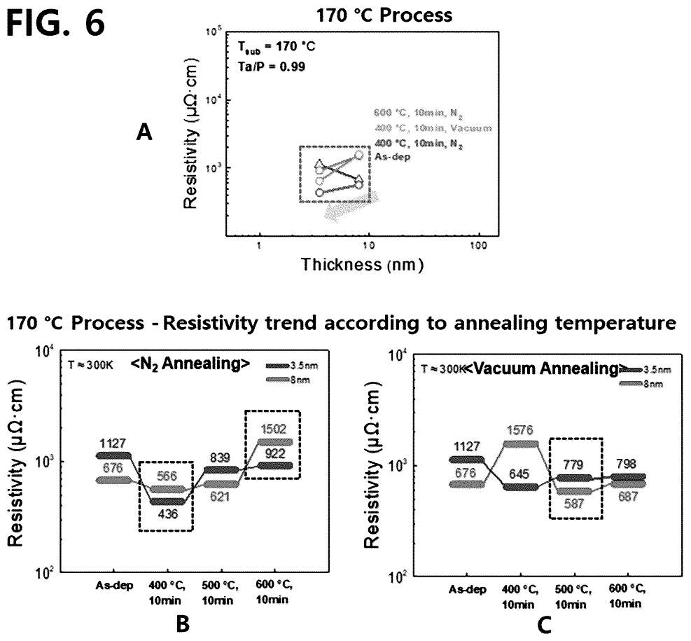

The resistivity value of the TaP ALD thin film of Example 2 was measured using a non-contact sheet resistance measurement method, and the results are shown in Tables 2 to 4 and FIGS. 5 to 6 below. At this time, FIG. 5 shows the resistivity value for a TaP ALD thin film fabricated at a target substrate and a deposition temperature of 250° C., and FIG. 6 shows the resistivity value for a TaP ALD thin film fabricated at a target substrate and deposition temperature of 170° C.

TABLE 2

| | Target substrate and deposition temperature: 250° C. | | | |
|---|---|---|---|---|
| | Whether | Annealing | Thin film | Resistivity |
| | annealing is | temperature in | thickness | value |
| Classification | performed | N₂ atmosphere | (nm) | (μΩ · cm) |
| TaP thin film | X | — | 3.5 | 4120 |
| TaP thin film | X | — | 8 | 500 |
| TaP thin film | ◯ | 400° C. | 3.5 | 7690 |
| TaP thin film | ◯ | 400° C. | 8 | 350 |
| TaP thin film | ◯ | 500° C. | 3.5 | 7690 |
| TaP thin film | ◯ | 500° C. | 8 | 250 |
| TaP thin film | ◯ | 600° C. | 3.5 | 910 |
| TaP thin film | ◯ | 600° C. | 8 | 340 |

TABLE 3

| | Target substrate and deposition temperature: 170° C. | | | |
|---|---|---|---|---|
| | Whether | Annealing | Thin film | Resistivity |
| | annealing is | temperature in | thickness | value |
| Classification | performed | N₂ atmosphere | (nm) | (μΩ · cm) |
| TaP thin film | X | — | 3.5 | 1127 |
| TaP thin film | X | — | 8 | 676 |
| TaP thin film | ◯ | 400° C. | 3.5 | 436 |
| TaP thin film | ◯ | 400° C. | 8 | 566 |
| TaP thin film | ◯ | 500° C. | 3.5 | 839 |
| TaP thin film | ◯ | 500° C. | 8 | 621 |
| TaP thin film | ◯ | 600° C. | 3.5 | 922 |
| TaP thin film | ◯ | 600° C. | 8 | 1502 |

TABLE 4

| | Target substrate and deposition temperature: 170° C. | | | |
|---|---|---|---|---|
| | | Annealing | | |
| | Whether | temperature | Thin film | Resistivity |
| | annealing is | in a vacuum | thickness | value |
| Classification | performed | atmosphere | (nm) | (μΩ · cm) |
| TaP thin film | ∘ | 400° C. | 3.5 | 645 |
| TaP thin film | ∘ | 400° C. | 8 | 1576 |
| TaP thin film | ∘ | 500° C. | 3.5 | 779 |
| TaP thin film | ∘ | 500° C. | 8 | 587 |
| TaP thin film | ∘ | 600° C. | 3.5 | 798 |
| TaP thin film | ∘ | 600° C. | 8 | 687 |

Referring to Table 2 and FIG. 5, in the case of the Ta-rich TaP ALD thin film deposited at 250° C., resistivity tends to increase as the thickness decreases regardless of the annealing conditions.

On the other hand, referring to Tables 3 to 4 and A to C of FIG. 6, in the case of a stoichiometric ALD thin film with Ta/P close to 1, deposited at 170° C., the resistivity was reversed in the thin film subjected to annealing at 400° C. to 600° C. in an N₂ atmosphere or vacuum atmosphere, although there was a difference in degree.

Looking at the trend of resistivity values according to the annealing temperature, the lowest resistivity value is shown when the annealing is performed at 400° C. for 10 minutes, and the resistivity value tends to increase when the annealing temperature is increased to 500° C. and 600° C. In particular, when annealing was performed at 400° C. for 10 minutes under an N₂ atmosphere, the reverse resistivity property and the lowest resistivity value were confirmed (B in FIG. 6). Through this, it was confirmed that the optimal annealing temperature for resistivity of TaP ALD thin films is 600° C. or lower, preferably 400° C.

In addition, it can be confirmed that the optimal annealing atmosphere for resistivity of TaP ALD thin films is N₂ atmosphere.

### Example 3: Fabrication of TaP ALD Thin Films

A TaP ALD thin film (x/y=0.99) represented by Chemical Formula 1-1 was fabricated under the same metal precursor and ALD deposition method as in Example 2 above, and a deposition temperature of 170° C. However, by changing the number of process cycles, a 3.5 nm thick TaP ALD thin film was fabricated (36 cycles based on a 3.5 nm thick target).

Then, a 3 nm thick SiNₓ ALD deposition layer (oxidation barrier layer) was formed on the ALD thin film, and then various thin films were fabricated by performing annealing at 400° C., 500° C., or 600° C. for 10 minutes under an N₂ atmosphere.

### Experimental Example 3: XRD Crystallinity Analysis Experiment

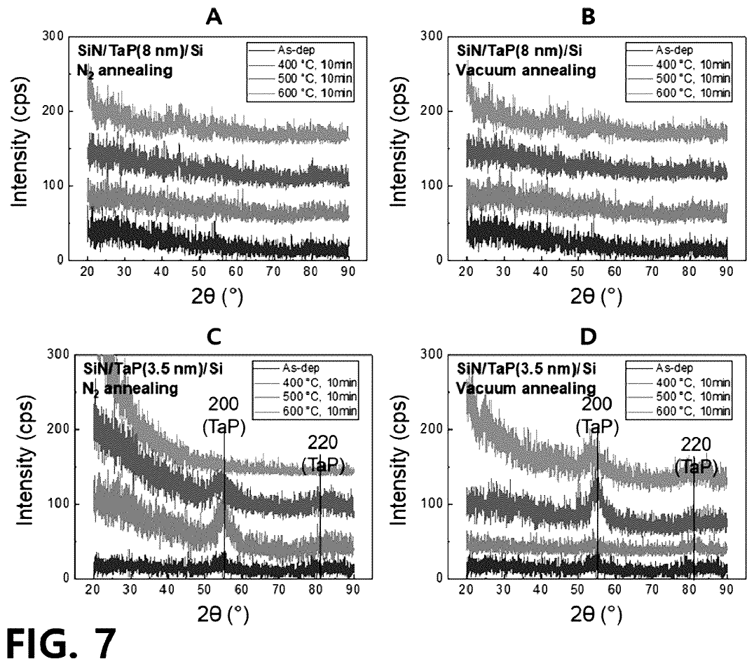

The crystallinity was analyzed by XRD analysis of topological Weyl semimetals in the thin films according to the annealing temperature for the TaP ALD thin films having a thickness of 8 nm fabricated under the deposition conditions of 170° C. in Example 2 and the TaP ALD thin films having a thickness of 3.5 nm fabricated in Example 3, and the results are shown A to D in FIG. 7. In this case, A of FIG. 7 shows a thin film thickness of 8 nm and annealing under N₂, B shows a thin film thickness of 8 nm and annealing under vacuum, C shows a thin film thickness of 3.5 nm and annealing under N₂, and D shows a thin film thickness of 3.5 nm and annealing under vacuum.

Referring to A and B of FIG. 7, it was confirmed that the TaP thin film of 8 nm has an amorphous shape regardless of whether the annealing is performed, the annealing temperature, and the annealing atmosphere.

On the other hand, referring to C and D of FIG. 7, the 3.5 nm TaP thin film had a peak between 55 and 60° during the annealing of 400° C., 500° C., and 600° C., which means that nanocrystals exist, and it was confirmed that the thinner the thickness, the more nanocrystals tend to occur, and it can be seen that when the annealing temperature is 400° C. and 500° C., a higher peak occurs between 55 and 60° than at 600° C. Through this, it was confirmed that when annealing is performed at 400° C. and 500° C., the nanocrystal ratio tends to increase slightly compared to the ALD thin film annealed at 600° C.

In addition, referring to the results of Experimental Example 2 and Experimental Example 3, when the resistivity value and crystallinity tendency according to the annealing temperature were reviewed, overall, when 400° C. annealing was performed for 10 minutes, the lowest resistivity value and high nanocrystallinity were shown, and when the annealing temperature was raised to 500° C. and 600° C., the resistivity value tended to increase and the nanocrystallinity tended to decrease.

Through this, it was confirmed that the resistivity optimized annealing temperature of the TaP ALD thin film was 600° C. or less, preferably 400° C., which was a result of an increase in conductivity due to nanocrystallinity.

What is claimed is:

1. ALD thin film with reverse resistivity, comprising:
a topological Weyl semimetal formed by atomic layer deposition (ALD),
wherein the resistivity value of the ALD thin film decreases as the thickness of the ALD thin film decreases, and
wherein the resistivity value of the ALD thin film decreases by 10 μΩ·cm or more per 1 nm decrease in the thickness of the ALD thin film.

2. The ALD thin film with reverse resistivity of claim 1, wherein the resistivity value satisfies 570 μΩ·cm or less when the thickness is 10 nm or less.

3. The ALD thin film with reverse resistivity of claim 1,
wherein the topological Weyl semimetal comprises a compound represented by Chemical Formula 1 or Chemical Formula 2 below:
MₓA_{y} [Chemical Formula 1]
where M is Ta (tantalum) or Nb (niobium), A is P (phosphorus) or As (arsenic), x and y mean a stoichiometric ratio, and x/y is 0.95 to 1.10,
M′ₓ(B₂)_{y} [Chemical Formula 2]
where M′ is W (tungsten) or Mo (molybdenum), B is Te (tellurium), x and y mean a stoichiometric ratio, and x/y is 0.95 to 1.10.

4. The ALD thin film with reverse resistivity of claim 1, wherein the topological Weyl semimetal is amorphous or nanocrystal-containing amorphous.

5. The ALD thin film with reverse resistivity of claim 1, wherein the ALD thin film does not contain nanocrystals when it exceeds 5 nm.

6. The ALD thin film with reverse resistivity of claim 3, wherein when the ALD thin film is less than or equal to 5 nm, the ALD thin film comprises nanocrystals having an average particle diameter smaller than the thickness of the thin film and an average particle diameter of 2.2 nm or less.

7. A manufacturing method for an ALD thin film with reverse resistivity, the manufacturing method comprising:
performing an ALD deposition process on a substrate using a metal precursor and a reactant to form an ALD deposition layer containing a compound represented by Chemical Formula 1 or Chemical Formula 2 below,
wherein the metal precursor comprises a Ta (tantalum) precursor, a Nb (niobium) precursor, a W (tungsten) precursor, or a Mo (molybdenum) precursor,
wherein when the metal precursor is a Ta precursor or an Nb precursor, the reactant comprises a P (phosphorus)-based compound or an As (arsenic)-based compound, and
wherein when the metal precursor is a W precursor or a Mo precursor, the reactant comprises a tellurium (Te)-based compound:
MₓA_{y} [Chemical Formula 1]
where M is Ta (tantalum) or Nb (niobium), A is P (phosphorus) or As (arsenic), x and y mean a stoichiometric ratio, and x/y is 0.95 to 1.10,
M′ₓ(B₂)_{y} [Chemical Formula 2]
where M′ is W (tungsten) or Mo (molybdenum), B is Te (tellurium), x and y mean a stoichiometric ratio, and x/y is 0.95 to 1.10.

8. The manufacturing method of claim 7, wherein the Ta precursor comprises at least one selected from TaCl₅, TaF₅, TaI₅, TaBr₅, TaNp₃Cl₂, Ta(NEtMe)₅, Ta(NEt)(NEt₂)₃, Ta(NEt₂)₅, Ta(NMe₂)₅, Ta(OEt)₅, Ta(N^{t}Bu)(^{t}PrAMD)₂(NMe₂), Ta(N^{t}Bu)(NEt₂)₃, Ta(N^{t}Bu)(^{t}Bu₂pz)₃, and Ta(N^{t}Am)(NMe₂)₃.

9. The manufacturing method of claim 7, wherein the Nb precursor comprises at least one selected from NbCl₅, NbF₅, Nb(OEt)₅, Nb(N^{t}Bu)(NEt₂)₂(Cp), Nb(N^{t}Bu)(NEt₂)₃, and Nb(N^{t}Bu)(NEtMe)₃.

10. The manufacturing method of claim 7, wherein the P-based compound comprises at least one selected from PH₃, P(NMe₂)₃, ^{t}BuPH₂, P₂O₅, and PO(OMe)₃.

11. The manufacturing method of claim 7, wherein the As-based compound comprises at least one selected from As, AsH₃, As(NMe₂)₃, (Et₃Si)₃As, ^{t}BuAsH₂, and EtAsH₂.

12. The manufacturing method of claim 7, wherein the W precursor comprises at least one selected from WCl₅, WF₆, W(CO)₆, WH₂Cp₂, W₂(NMe₂)₆, W(N^{t}Bu)₂(NMe₂)₂, (C₆H₁₀)₃(CO)W, WH₂(ⁱPrCp)₂, and WO₂(^{t}BuAMD)₂.

13. The manufacturing method of claim 7, wherein the Mo precursor comprises at least one selected from MoCl₅, MoF₆, MoO₂Cl₂, Mo(CO)₆, Mo(NMe₂)₄, Mo(C₆H₅C₂H₅)₂, Mo(MeCp)(CO)₂(NO), MoH₂(ⁱPrCp)₂, Mo(N^{t}Bu)₂(NEt₂)₂, Mo(N^{t}Bu)₂(NMe₂)₂, Mo(C₅H₁₁N)₂(C₅H₁₁NH)₂, Mo(^{t}BuN)₂(S^{t}Bu)₂, and MoCp(CO)₂(NO).

14. The manufacturing method of claim 7, wherein the ALD deposition process is performed by thermal atomic layer deposition (thermal ALD) or plasma enhanced atomic layer deposition (PE-ALD) process.

15. The manufacturing method of claim 7,
wherein the ALD deposition process performs, once or repeatedly more than once, a cycle, the cycle comprising:
step 1 of forming a metal deposition layer on a target substrate by supplying a vaporized metal precursor into a reaction chamber via a carrier gas;
step 2 of purging the inside of the chamber with a purge gas;
step 3 of supplying a reactant into the chamber to form a deposition layer containing a compound represented by Chemical Formula 1 or Chemical Formula 2 above formed by reacting the metal deposition layer with the reactant;
step 4 of purging the inside of the chamber with a purge gas after performing step 3;
step 5 of treating the inside of the chamber with H₂ after performing step 4; and
step 6 of purging the inside of the chamber with a purge gas after performing step 5.

16. The manufacturing method of claim 15,
wherein the temperature of the target substrate in step 1 is 100 to 500° C., and
wherein the process temperature in steps 1 to 3 is 100 to 500° C.

17. The manufacturing method of claim 15, wherein the H₂ treatment in step 5 is performed by H₂ gas treatment, H₂ plasma treatment, or H₂ radical treatment.

18. The manufacturing method of claim 7,
wherein after completing the ALD deposition process, an oxidation barrier film is further formed on the surface protruding outward from the ALD deposition layer, followed by an annealing process, and
wherein the annealing is performed at 300 to 850° C. in a vacuum atmosphere or an inert gas.

19. The manufacturing method of claim 17, wherein the oxidation barrier film is a silicon nitride (SiNₓ) ALD deposition layer with a thickness of 1 to 10 nm.

20. An interconnect comprising the ALD thin film with reverse resistivity of claim 1.
